(19) United States
(12) Patent Application Publication
(10) Pub. No.: US 2018/0047936 A1
(43) Pub. Date: Feb. 15, 2018

(54) ELECTRONIC COMPONENT AND METHOD FOR PRODUCING AN ELECTRONIC COMPONENT

(71) Applicant: OSRAM OLED GmbH, Regensburg (DE)

(72) Inventor: Simon Schicktanz, Regensburg (DE)

(21) Appl. No.: 15/706,830

(22) Filed: Sep. 18, 2017

Related U.S. Application Data
(63) Continuation of application No. 14/398,145, filed on Oct. 31, 2014, now abandoned.

(30) Foreign Application Priority Data
May 2, 2012 (DE) 10 2012 207 229.2

(51) Int. Cl. H01L 51/52; H01L 51/56; H01L 51/44

(52) U.S. Cl. CPC H01L 51/5237; H01L 51/5253; H01L 51/448; H01L 51/5203; H01L 51/5206; H01L 51/56; H01L 51/441; H01L 51/5246; H01L 51/5221; H01L 51/5268; H01L 51/5256; H01L 2251/5361; H01L 2924/0002

(57) ABSTRACT

In various embodiment examples, an electronic component is provided, the electrical component comprising an electrically active area, having a first contact pad; a second contact pad; an organic functional layer structure between the first contact pad and the second contact pad; at least one electrical connection, which is coupled to the first contact pad or to the second contact pad, and an encapsulation, which partially covers the electrically conductive area in such a way that part of the first contact pad or of the second contact pad is exposed.

### CROSS-REFERENCE TO RELATED APPLICATIONS

The present application is a continuation of U.S. patent application Ser. No. 14/398,145 filed on Oct. 31, 2014, which is national stage entry according to 35 U.S.C. §371 of PCT application No.: PCT/EP2013/058317 filed on Apr. 22, 2013, which claims priority from German application No.: 10 2012 207 229.2 filed on May 2, 2012; the contents all of which are incorporated herein by reference in their entirety.

The claims in the instant application are different than those of the parent application or other related applications. The Applicant therefore rescinds any disclaimer of claim scope made in the parent application or any predecessor application in relation to the instant application. The Examiner is therefore advised that any such previous disclaimer and the cited references that it was made to avoid, may need to be revisited. Further, the Examiner is also reminded that any disclaimer made in the instant application should not be read into or against the parent application.

### TECHNICAL FIELD

In various embodiments, an electronic component and a method for producing an electronic component are provided.

### BACKGROUND

An electronic component, for example an organic optoelectronic component, includes at least two contact pads and, for example, an organic functional layer system therebetween. An electrical terminal that supplies the organic functional layer system with current is coupled to the contact pads.

The electrical connection of the electrical terminal to the contact pad is conventionally secured mechanically by means of a soldering connection at a soldering location. The exposed surface of the contact pads, for example chromium, and the soldering tin are often not compatible, i.e. miscible, with one another. An arbitrary flow of the soldering tin on the exposed surface of the contact pad may occur as a result. The flowing soldering tin can then make it more difficult to precisely position the terminals on the soldering location.

Conventional methods for restricting the solderable regions use soldering resist or soldering pad forms (constrictions).

A further problem when producing an electrical connection to a component is posed by polarity reversal, incorrect polarity or short-circuiting of an electronic component in the case of similarly shaped poles, for example contact pads.

### SUMMARY

In various embodiments, an electronic component and a method for producing an electronic component are provided with which it is possible to form precise soldering connections and polarity reversal protection.

In the context of this description, an organic substance can be understood to mean a carbon compound which, regardless of the respective state of matter, is present in chemically uniform form and is characterized by characteristic physical and chemical properties. Furthermore, in the context of this description, an inorganic substance can be understood to mean a compound which, regardless of the respective state of matter, is present in chemically uniform form and is characterized by characteristic physical and chemical properties, without carbon or a simple carbon compound. In the context of this description, an organic-inorganic substance (hybrid substance) can be understood to mean a compound which, regardless of the respective state of matter, is present in chemically uniform form and is characterized by characteristic physical and chemical properties, including compound portions which contain carbon and are free of carbon. In the context of this description, the term “substance” encompasses all abovementioned substances, for example an organic substance, an inorganic substance, and/or a hybrid substance. Furthermore, in the context of this description, a substance mixture can be understood to mean something which has constituents consisting of two or more different substances, the constituents of which are very finely dispersed, for example. A substance class should be understood to mean a substance or a substance mixture including one or more organic substance(s), one or more inorganic substance(s) or one or more hybrid substance(s). The term “material” can be used synonymously with the term “substance”.

In various embodiments, an electronic component is provided, the component including: an electrically active region, including: a first contact pad; a second contact pad; an organic functional layer structure between the first contact pad and the second contact pad; at least one electrical terminal which is coupled to the first contact pad or to the second contact pad, and an encapsulation that partly covers the electrically conductive region in such a way that a part of the first contact pad or of the second contact pad is exposed.

In one embodiment, the optoelectronic component may include one or a plurality of contact pads, for example 2 contact pads, 3 contact pads, 4 contact pads, 5 contact pads or more. The number of contact pads may be dependent on the areal size of the optoelectronic component and the demand for the areal homogeneity of the emitted or absorbed electromagnetic radiation of the organic optoelectronic component. Furthermore, the number of contact pads of an optoelectronic component may be dependent on the number of further optoelectronic component which are connected to an optoelectronic component, for example by being connected thereto or interconnected therewith.

In another embodiment, at least one of the contact pads may have a different polarity than another region of the same contact pad and/or may have a different polarity than the at least one other contact pad.

In this case, polarity may be understood to mean different exit points or entrance points of a type of charge carriers, for example electrons or holes, of a current source.

In another embodiment, the first contact pad, the organic functional layer structure and the second contact pad may be arranged one above another in a planar fashion.

In another embodiment, the first contact pad, the organic functional layer structure and the second contact pad may be arranged alongside one another in a planar fashion.

In various embodiments, the first contact pad, the organic functional layer structure and the second contact pad may be arranged one above another in a planar fashion or the first contact pad, the organic functional layer structure and the second contact pad may be arranged alongside one another in a planar fashion.

In another embodiment, the first contact pad and/or the second contact pad may at least partly surround the organic functional layer structure.

In another embodiment, the first contact pad and/or the second contact pad may be at least partly surrounded by the organic functional layer structure.

In another embodiment, the first contact pad and/or the second contact pad may include an electrically conductive region and an electrically insulating region; and wherein the exposed regions of the first contact pad and/or of the second contact pad are free of an insulating region above or on a conductive region. The electrically conductive region of the first contact pad and/or of the second contact pad may be coupled to one of the electrodes of the organic functional layer system.

In another embodiment, the electrically conductive region may be formed in a self-supporting fashion or may be applied on a carrier.

In another embodiment, the substance or the substance mixture of the first contact pad and/or the substance or the substance mixture of the second contact pad may include or be formed from a substance from the group of substances consisting of: Cu, Ag, Au, Pt, CuSn, Cr, Al.

In another embodiment, the encapsulation may be formed as an insulating region of the first contact pad and/or of the second contact pad and the substance or the substance mixture of the encapsulation may include or be formed from a substance or a substance mixture from the group of substances: aluminum oxide, zinc oxide, zirconium oxide, titanium oxide, hafnium oxide, tantalum oxide, lanthanum oxide, silicon oxide, silicon nitride, silicon oxynitride, indium tin oxide, indium zinc oxide, aluminum-doped zinc oxide, and mixtures and alloys thereof.

In another embodiment, the electrically insulating region may be formed as encapsulation on or above the electrically conductive layer, wherein the encapsulation may have a constitution similar or identical to the thin-film encapsulation of the organic functional layer structure, for example may be deposited in the same process.

In another embodiment, for coupling the electrical terminal to the first contact pad and/or the second contact pad the electrical terminal in the exposed region of the first contact pad and/or of the second contact pad may be formed a physical and electrical connection or only an electrical connection to the first contact pad.

In another embodiment, the electrical terminal in physical contact with the encapsulation may have or form no electrical connection to the first contact pad and/or the second contact pad.

In another embodiment, the first contact pad and/or the second contact pad may have a configuration including two or more exposed regions in the encapsulation.

In another embodiment, the configuration of the exposed regions of the encapsulation for the first contact pad may be formed differently relative to the configuration of the exposed regions of the encapsulation of the second contact pad, wherein not every contact pad may exhibit exposed regions, rather the regions to be exposed may be exposed as necessary.

In another embodiment, one exposed region or a plurality of exposed regions may be formed on the first contact pad and/or on the second contact pad, wherein the shape of said regions and the distance between the two or more exposed regions may be formed differently. Moreover, the position of the at least one exposed region on the contact pad may be formed identically or differently relative to the position of exposed regions on other contact pads.

The individual exposed regions may have an identical or different cross section.

The exposed region may have a geometrical shape or a part of the geometrical shape from the group of the following geometrical bodies: cylinder, cone, truncated cone, sphere, hemisphere, cube, parallelepiped, pyramid, truncated pyramid, prism, or a polyhedron.

Exposure of conductive regions on contact pads may be formed on all sides of the component and also simultaneously.

In an optoelectronic component, it is possible to form the contact pads with the exposed regions on the side with the active surface, i.e. the side by or from which electromagnetic radiation is absorbed or emitted and which may also be designated as the top side, or on contact pads on the rear side or the side faces of the optoelectronic component in non-visible and/or optically inactive regions.

In another embodiment, the configuration of the exposed regions of the encapsulation may be formed in such a way that in the case of corresponding polarity of electrical terminal and contact pad an electrical connection of the terminal to the contact pad may form. In the case of non-corresponding polarity of the terminals relative to the contact pads, polarity reversal protection may be formed as a result.

In another embodiment, the configuration of the exposed regions of the encapsulation for contact pads having identical polarity may be formed identically.

In another embodiment, the configurations of the exposed regions of the contact pads may be designed in such a way that an electrical connection is formed only in the case of an alignment of the component with regard to terminals formed in a stationary fashion, for example if the exposed regions of each contact pad are shaped differently and/or each contact pad has a different number of exposed regions and/or a different configurations of exposed regions.

In another embodiment, the difference between the layer cross section of the encapsulation of the first contact pad relative to the encapsulation of the second contact pad may include a different parameter from the group of the following parameters: the substance or the substance mixture; the homogeneity, the number of layers, the layer sequence and the layer thickness.

In another embodiment, in the case of corresponding polarity of the first contact pad and/or of the second contact pad with the respective terminals, the exposed regions of the encapsulation may be formed complementarily to the embodiment of the terminals.

In another embodiment, the complementary embodiment may include at least one complementary parameter from the group of the following parameters: shape; topography; and chemical constitution of the surface.

In another embodiment, at least one exposed region of the first contact pad and/or of the second contact pad may be coupled to an electrical terminal by means of a cohesive connection.

In another embodiment, the cohesive connection at least in one of the exposed regions may include a substance or a substance mixture of a cohesive method from the group of the following cohesive connections: welding; soldering; or adhesive bonding, i.e. for example a soldering tin, adhesive or the like.

In another embodiment, in the case of a plurality of exposed regions on the first contact pad and/or the second contact pad, the individual exposed regions of the first contact pad and/or of the second contact pad may simultaneously also have mutually different positively locking and/or cohesive connections.

In another embodiment, the shape of the exposed regions of the encapsulation may form an aligning effect on the substance or the substance mixture used for the cohesive connection process.

The regions to be exposed may be evaporated for example by means of a UV laser, for example by means of a pulsed ns laser, or blasted or exposed by means of a pulsed fs laser. Further methods may include for example wet-chemical etching and/or chemical and/or mechanical grinding or polishing.

In another embodiment, the substance or the substance mixture of the encapsulation layer may be formed as a diffusion barrier for the substance or the substance mixture of the cohesive connection.

In another embodiment, the coupling of at least one exposed region of a first contact pad and/or of a second contact pad to an electrical terminal may be formed by means of positively locking engagement, gravitational force or spring force.

In another embodiment, the shape of the exposed regions of the encapsulation and/or the shape of the terminal may be shaped in such a way that an aligning effect on the physical contact of the terminal with the exposed region of a first contact pad and/or of a second contact pad is formed.

In another embodiment, the electronic component may include an organic optoelectronic component, preferably an organic light emitting diode or an organic solar cell.

In various embodiments, a method for producing an electronic component is provided, the method including: forming an electrically active region, including: forming a first contact pad; forming an organic functional layer structure; and forming a second contact pad; at least one electrical terminal which is coupled to the first contact pad or to the second contact pad, and an encapsulation that is partly removed from the first contact pad or from the second contact pad in such a way that a part of the first contact pad or of the second contact pad is exposed.

In one embodiment of the method, the first contact pad, the organic functional layer structure and the second contact pad may be formed one above another in a planar fashion.

In another embodiment of the method, the first contact pad, the organic functional layer structure and the second contact pad may be formed alongside one another in a planar fashion.

In another embodiment of the method, the first contact pad and/or the second contact pad may at least partly surround the organic functional layer structure.

In another embodiment of the method, the first contact pad and/or the second contact pad may be at least partly surrounded by the organic functional layer structure, for example by virtue of the fact that a plurality of organic functional layer structures share at least one common contact pad.

In another embodiment of the method, the substance or the substance mixture for forming the first contact pad and/or the substance or the substance mixture for forming the second contact pad may include or be formed from a substance from the group of the following substances: Cu, Ag, Au, Pt, CuSn, Cr, Al.

In another embodiment of the method, the first contact pad and/or the second contact pad may include an electrically conductive region and an electrically insulating region; and wherein the exposed regions of the first contact pad and/or of the second contact pad are free of an insulating region above or on a conductive region.

In another embodiment, exposing an electrically conductive region of the first contact pads and/or of the second contact pad below the electrically insulating region, i.e. removing the electrically insulating region above or on the electrically conductive region, may be formed by means of a mechanical process or a ballistic process.

Mechanically exposing a conductive region of a contact pad may be formed for example by means of a glass fiber brush.

Ballistically exposing a conductive region of a contact pad may be realized for example by means of bombardment of the region to be exposed with particles, molecules, atoms, ions, electrons and/or photons.

A device for ballistic exposure by means of photons may be formed for example as a laser, formed for example with a wavelength in the range of approximately 200 nm to approximately 1500 nm, for example in a focused fashion, for example with a focus diameter in a range of approximately 10 μm to approximately 2000 μm; for example in a pulsed fashion, for example with a pulse duration in the range of approximately 100 fs to approximately 0.5 ms; for example with a power in a range of approximately 50 mW to approximately 1000 mW, for example with a power density of 100 kW/cm2 to approximately 10 GW/cm2, with a repetition rate in a range of approximately 100 Hz to approximately 1000 Hz.

In another embodiment of the method, for coupling the electrical terminal to the first contact pad and/or the second contact pad the electrical terminal in the exposed region of the first contact pad and/or of the second contact pad may form a physical and electrical connection or only an electrical connection to the first contact pad or to the second contact pad.

In this case, the electrical terminal may be formed as part of a holding device of the organic optoelectronic component, for example for energizing an organic light emitting diode.

In another embodiment of the method, the encapsulation may be formed as an insulating region of the first contact pad and/or of the second contact pad and the substance or the substance mixture of the encapsulation may include or be formed from a substance or a substance mixture from the group of substances: aluminum oxide, zinc oxide, zirconium oxide, titanium oxide, hafnium oxide, tantalum oxide, lanthanum oxide, silicon oxide, silicon nitride, silicon oxynitride, indium tin oxide, indium zinc oxide, aluminum-doped zinc oxide, and mixtures and alloys thereof.

In another embodiment of the method, the electrical terminal in physical contact with the encapsulation may have or form no electrical connection to the first contact pad and/or the second contact pad.

In another embodiment of the method, when exposing the regions of the first contact pad and/or when exposing the regions of the second contact pad, a configuration including two or more exposed regions may be formed in the encapsulation of the first contact pad and/or of the second contact pad.

In another embodiment of the method, in the case of the first contact pad and/or in the case of the second contact pad a different number of exposed regions may be formed, for example none, one, two, three or more.

The exposed regions can, among one another and/or relative to the exposed regions of other contact pads, have different distances from one another.

The distance between the electrical terminals and/or the shape of the electrical terminals does not correspond to the distance between the exposed regions of the contact pad in the case of incorrect alignment, i.e. polarity reversal of the component relative to the electrical terminals. Polarity reversal protection may be formed as a result.

The exposed regions on a contact pad and relative to the exposed regions of other contact pads may have a different shape and/or extent. As a result, it is possible to form polarity reversal protection which may prevent incorrect polarity, polarity reversal or short-circuiting of an optoelectronic component, for example in the case of stationary terminals of a holding device, for example a base device.

In another embodiment of the method, the configuration of the exposed regions of the encapsulation for the first contact pad may be formed differently relative to the configuration of the exposed regions of the encapsulation of the second contact pad.

In another embodiment of the method, the configuration of the exposed regions of the encapsulation may be formed in such a way that in the case of corresponding polarity of electrical terminal and contact pad an electrical connection of the electrical terminal to the contact pad is formed.

In another embodiment of the method, the configuration of the exposed regions of the encapsulation for the first contact pad and/or for the second contact pad having identical polarity may be formed identically.

In another embodiment of the method, on the at least one contact pad the regions of the encapsulation may be exposed in such a way that only an alignment of the organic optoelectronic component relative to the electrical terminals leads to an electrical connection.

An unambiguous alignment of a component may be formed, without altering the outer shape of the holding device or of the electronic component, for example if each contact pad or each electrical terminal complementary thereto is formed individually, i.e. uniquely, with regard to shape and distance from other exposed regions or electrical terminals.

Depending on the constitution and embodiment of the electronic component, contact pads lying opposite in a planar fashion, for example, may have an identical polarity and thus enable for example a homogeneous energization of one optoelectronic component or an interconnection of a plurality of optoelectronic components.

In another embodiment of the method, the exposed region of the encapsulation of the first contact pad and/or of the second contact pad may be formed complementarily to the shape of the respective terminal.

In another embodiment of the method, complementarily forming the exposed region of the encapsulation and of the terminal may include at least one parameter from the group of the following parameters: the shape; the topography; and the chemical constitution of the surface.

In another embodiment of the method, the coupling of the terminal to the exposed part of the first contact pad or to the exposed part of the second contact pad may include a cohesive connection process.

In another embodiment of the method, the cohesive connection may include a joining method from the group of the following methods: welding; soldering; or adhesive bonding.

In another embodiment of the method, the conductive region may be exposed in such a way that when producing the physical contact of a terminal with a contact pad, the shape of the exposed regions of the encapsulation form an aligning effect on the substance or the substance mixture used for the cohesive connection.

For the cohesive connection of an electrical terminal to the conductive region in the exposed region of the first contact pad and/or of the second contact pad, the exposed regions of the encapsulation may be filled partly or wholly with the substance or substance mixture for the cohesive connection.

The substance or the substance mixture of the cohesive connection may be, prior to the connection process, in a non-solid state, for example liquid or viscous, for example a non-cured epoxy, a thermally conductive paste, soldering tin, or some other liquid or liquefied metal or metal compound, for example metal alloy.

The substance or the substance mixture of the encapsulation may be formed as impermeable to the substance or the substance mixture of the cohesive connection, as a result of which the encapsulation forms a diffusion barrier for the substance or the substance mixture of the cohesive connection.

In another embodiment of the method, the substance or the substance mixture of the encapsulation layer may be formed as a diffusion barrier for the substance or the substance mixture of the cohesive connection.

The shape of the exposed regions, for example of a truncated cone, may have an aligning effect, i.e. position-directing effect, for the substance or the substance mixture of the cohesive connection and an electrical terminal if the electrical terminal is guided into the exposed region. The aligning effect may be reinforced if the electrical terminal is shaped complementarily to the exposed region.

By means of the aligning effect, it is possible to compensate for deviations from the complementary alignment of the electrical terminals relative to the exposed regions by means of a position-correcting shape, for example tapering.

In the case of an electrically conductive substance or substance mixture of the cohesive connection, by means of just coupling an electrical terminal to the substance or the substance mixture of the cohesive connection it is possible to form an electrical connection between electrical terminal and exposed electrically conductive region of the contact pad, i.e. the extent of the electrical terminals may be smaller than the extent of the exposed regions. The alignment of the electrical terminals relative to the exposed regions may be simplified as a result.

The extent of the exposed regions may be chosen with a magnitude such that it is possible for the substance or the substance mixture of the cohesive connection, for example the soldering tin, to flow below the pin, as a result of which the electrical terminal may be prevented from slipping. An electrical terminal may be embodied for example in the form of a pin.

In this case, preventing the substance or the substance mixture of the cohesive connection from running may be intensified or reduced by means of adapting the surface tension of the substance or the substance mixture of the encapsulation and the surface tension of the substance or the substance mixture of the cohesive connection.

In the case of a non-conductive substance or substance mixture of the cohesive connection, it is possible to form an electrical connection between electrical terminal and electrically conductive region of the contact pad by means of physical contact.

In another embodiment of the method, the coupling of a terminal to the exposed region of the first contact pad or to the exposed region of the second contact pad may be formed by means of positively locking engagement, gravitational force or spring force.

In another embodiment of the method, contact pads of identical polarity may be electrically connected to one another by means of electrical bridges, i.e. connected in parallel, for example with conventional wirings which may be fixed with a cohesive or positively locking connection.

Defined positions for the electrical bridges may be realized by means of the exposed regions. The defined positions may be used for example for forming the bridges in an automated fashion, for example by means of a robot.

By means of the exposed regions, connecting contact pads in parallel may furthermore be simplified, since only one cable is processed/held per soldering location, for example.

By means of the formation of electrical bridges by means of the exposed regions, cohesive connections, for example soldering locations, may be formed serially, such that soldering locations that had already been formed may remain, i.e. are no longer released or altered.

In another embodiment of the method, the first contact pad and/or the second contact pad may have a plurality of exposed regions and may be connected to an electrical terminal, wherein more than one contact pad of identical polarity may be connected in parallel and energized by means of electrical bridges with the unoccupied, exposed regions.

In another embodiment of the method, exposed regions that are not used for the energization may be used for aligning and/or fixing the electronic component.

In another embodiment of the method, the electronic component may include an organic optoelectronic component, preferably an organic light emitting diode or an organic solar cell.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of the disclosed embodiments. In the following description, various embodiments described with reference to the following drawings, in which:

FIG. 1 shows a schematic cross-sectional view of an optoelectronic component, in accordance with various embodiments;

FIG. 2 shows a schematic plan view of the rear side of an optoelectronic component, in accordance with various embodiments;

FIG. 3 shows a schematic cross-sectional view of a contact pad of an optoelectronic component, in accordance with various embodiments;

FIG. 4 shows a schematic cross-sectional view of a contact pad of an optoelectronic component, in accordance with various embodiments;

FIG. 5 shows a schematic cross-sectional view of an electrical cohesive connection of an optoelectronic component to electrical contacts before the coupling, in accordance with various embodiments;

FIG. 6 shows a schematic cross-sectional view of an electrical cohesive connection of an optoelectronic component to electrical contacts after the coupling, in accordance with various embodiments;

FIG. 7 shows a schematic cross-sectional view of an electrical positively locking connection of an optoelectronic component to electrical contacts before the coupling, in accordance with various embodiments;

FIG. 8 shows a schematic cross-sectional view of an electrical positively locking connection of an optoelectronic component to electrical contacts after the coupling, in accordance with various embodiments;

FIG. 9 shows a schematic plan view of the rear side of an optoelectronic component with exposed conductive regions, in accordance with various embodiments;

FIG. 10 shows a schematic illustration of polarity reversal protection of an optoelectronic component in the case of incorrect polarity, in accordance with various embodiments;

FIG. 11 shows a schematic illustration of polarity reversal protection of an optoelectronic component in the case of correct polarity, in accordance with various embodiments;

FIG. 12 shows a schematic illustration of a parallel connection of an optoelectronic component, in accordance with various embodiments; and

FIG. 13 shows a schematic illustration of a specific embodiment of an optoelectronic component.

### DETAILED DESCRIPTION

In the following detailed description, reference is made to the accompanying drawings, which form part of this description and show for illustration purposes specific embodiments in which the disclosure may be implemented. In this regard, direction terminology such as, for instance, “at the top”, “at the bottom”, “at the front”, “at the back”, “front”, “rear”, etc. is used with respect to the orientation of the figure(s) described. Since component parts of embodiments may be positioned in a number of different orientations, the direction terminology serves for illustration and is not restrictive in any way whatsoever. It goes without saying that other embodiments may be used and structural or logical changes may be made, without departing from the scope of protection of the present disclosure. It goes without saying that the features of the various embodiments described herein may be combined with one another, unless specifically indicated otherwise. Therefore, the following detailed description should not be interpreted in a restrictive sense, and the scope of protection of the present disclosure is defined by the appended claims.

In the context of this description, the terms “connected” and “coupled” are used to describe both a direct and an indirect connection and a direct or indirect coupling. In the figures, identical or similar elements are provided with identical reference signs, insofar as this is expedient.

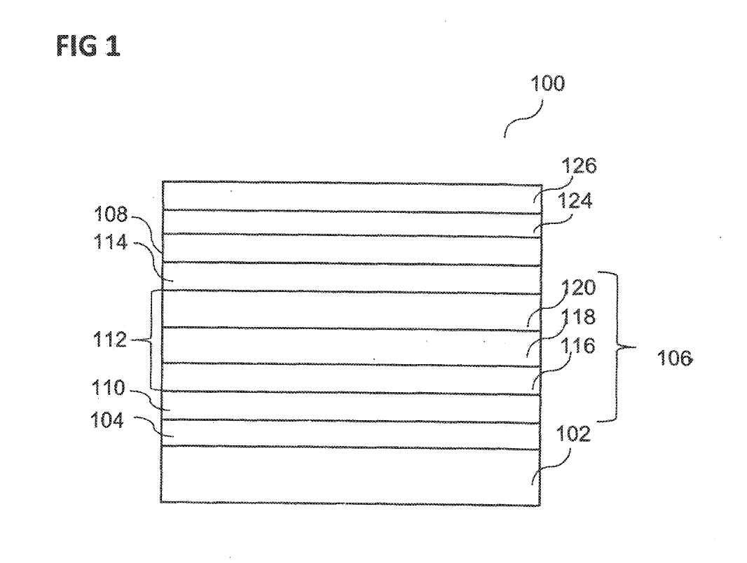

FIG. 1 shows a schematic cross-sectional view of an optoelectronic component, in accordance with various embodiments.

The light emitting component 100 in the form of an organic light emitting diode 100 may have a carrier 102. The carrier 102 may serve for example as a carrier element for electronic elements or layers, for example light emitting elements. By way of example, the carrier 102 may include or be formed from glass, quartz, and/or a semiconductor material or any other suitable material. Furthermore, the carrier 102 may be a plastic film or a laminate including one or including a plurality of plastic films. The plastic may include or be formed from one or more polyolefins (for example high or low density polyethylene (PE) or polypropylene (PP)). Furthermore, the plastic may include or be formed from polyvinyl chloride (PVC), polystyrene (PS), polyester and/or polycarbonate (PC), polyethylene terephthalate (PET), polyether sulfone (PES) and/or polyethylene naphthalate (PEN). The carrier 102 may include one or more of the materials mentioned above. The carrier 102 may be embodied as translucent or even transparent.

In various embodiments, the term “translucent” or “translucent layer” may be understood to mean that a layer is transmissive to light, for example to the light generated by the light emitting component, for example in one or more wavelength ranges, for example to light in a wavelength range of visible light (for example at least in a partial range of the wavelength range of from 380 nm to 780 nm). By way of example, in various embodiments, the term “translucent layer” should be understood to mean that substantially the entire quantity of light coupled into a structure (for example a layer) is also coupled out from the structure (for example layer), wherein part of the light may be scattered in this case.

In various embodiments, the term “transparent” or “transparent layer” may be understood to mean that a layer is transmissive to light (for example at least in a partial range of the wavelength range of from 380 nm to 780 nm), wherein light coupled into a structure (for example a layer) is also coupled out from the structure (for example layer) substantially without scattering or light conversion. Consequently, in various embodiments, “transparent” should be regarded as a special case of “translucent”.

For the case where, for example, a light emitting monochromatic or emission spectrum-limited electronic component is intended to be provided, it suffices for the optically translucent layer structure to be translucent at least in a partial range of the wavelength range of the desired monochromatic light or for the limited emission spectrum.

In various embodiments, the organic light emitting diode 100 (or else the light emitting components in accordance with the embodiments that have been described above or will be described below) may be designed as a so-called top and bottom emitter. A top and bottom emitter may also be designated as an optically transparent component, for example a transparent organic light emitting diode.

In various embodiments, a barrier layer 104 may optionally be arranged on or above the carrier 102. The barrier layer 104 may include or consist of one or more of the following materials: aluminum oxide, zinc oxide, zirconium oxide, titanium oxide, hafnium oxide, tantalum oxide, lanthanum oxide, silicon oxide, silicon nitride, silicon oxynitride, indium tin oxide, indium zinc oxide, aluminum-doped zinc oxide, and mixtures and alloys thereof. Furthermore, in various embodiments, the barrier layer 104 may have a layer thickness in a range of approximately 0.1 nm (one atomic layer) to approximately 5000 nm, for example a layer thickness in a range of approximately 10 nm to approximately 200 nm, for example a layer thickness of approximately 40 nm.

An electrically active region 106 of the light emitting component 100 may be arranged on or above the barrier layer 104. The electrically active region 106 may be understood as the region of the light emitting component 100 wherein an electric current flows for the operation of the light emitting component 100. In various embodiments, the electrically active region 106 may include a first electrode 110, a second electrode 114 and an organic functional layer structure 112, as will be explained in even greater detail below.

In this regard, in various embodiments, the first electrode 110 (for example in the form of a first electrode layer 110) may be applied on or above the barrier layer 104 (or, if the barrier layer 104 is not present, on or above the carrier 102). The first electrode 110 (also designated hereinafter as bottom electrode 110) may be formed from an electrically conductive material, such as, for example, a metal or a transparent conductive oxide (TCO) or a layer stack including a plurality of layers of the same metal or different metals and/or the same TCO or different TCOs. Transparent conductive oxides are transparent conductive materials, for example metal oxides, such as, for example, zinc oxide, tin oxide, cadmium oxide, titanium oxide, indium oxide, or indium tin oxide (ITO). Alongside binary metal-oxygen compounds, such as, for example, ZnO, SnO2, or In2O3, ternary metal-oxygen compounds, such as, for example, AlZnO, Zn2SnO4, CdSnO3, ZnSnO3, MgIn2O4, GaInO3, Zn2In2O5 or In4Sn3O12, or mixtures of different transparent conductive oxides also belong to the group of TCOs and may be used in various embodiments. Furthermore, the TCOs do not necessarily correspond to a stoichiometric composition and may furthermore be p-doped or n-doped.

In various embodiments, the first electrode 110 may include a metal; for example Ag, Pt, Au, Mg, Al, Ba, In, Ag, Au, Mg, Ca, Sm or Li, and compounds, combinations or alloys of these materials.

In various embodiments, the first electrode 110 may be formed by a layer stack of a combination of a layer of a metal on a layer of a TCO, or vice versa. One example is a silver layer applied on an indium tin oxide layer (ITO) (Ag on ITO) or ITO-Ag-ITO multilayers.

In various embodiments, the first electrode 110 may provide one or a plurality of the following materials as an alternative or in addition to the abovementioned materials: networks composed of metallic nanowires and nanoparticles, for example composed of Ag; networks composed of carbon nanotubes; graphene particles and graphene layers; networks composed of semiconducting nanowires.

Furthermore, the first electrode 110 may include electrically conductive polymers or transition metal oxides or transparent electrically conductive oxides.

In various embodiments, the first electrode 110 and the carrier 102 may be formed as translucent or transparent. In the case where the first electrode 110 is formed from a metal, the first electrode 110 may have for example a layer thickness of less than or equal to approximately 25 nm, for example a layer thickness of less than or equal to approximately 20 nm, for example a layer thickness of less than or equal to approximately 18 nm. Furthermore, the first electrode 110 may have for example a layer thickness of greater than or equal to approximately 10 nm, for example a layer thickness of greater than or equal to approximately 15 nm. In various embodiments, the first electrode 110 may have a layer thickness in a range of approximately 10 nm to approximately 25 nm, for example a layer thickness in a range of approximately 10 nm to approximately 18 nm, for example a layer thickness in a range of approximately 15 nm to approximately 18 nm.

Furthermore, for the case where the first electrode 110 is formed from a transparent conductive oxide (TCO), the first electrode 110 may have for example a layer thickness in a range of approximately 50 nm to approximately 500 nm, for example a layer thickness in a range of approximately 75 nm to approximately 250 nm, for example a layer thickness in a range of approximately 100 nm to approximately 150 nm.

Furthermore, for the case where the first electrode 110 is formed from, for example, a network composed of metallic nanowires, for example composed of Ag, which may be combined with conductive polymers, a network composed of carbon nanotubes which may be combined with conductive polymers, or from graphene layers and composites, the first electrode 110 may have for example a layer thickness in a range of approximately 1 nm to approximately 500 nm, for example a layer thickness in a range of approximately 10 nm to approximately 400 nm, for example a layer thickness in a range of approximately 40 nm to approximately 250 nm.

The first electrode 110 may be formed as an anode, that is to say as a hole-injecting electrode, or as a cathode, that is to say as an electron-injecting electrode.

The first electrode 110 may have a first electrical contact pad, to which a first electrical potential (provided by an energy source (not illustrated), for example a current source or a voltage source) may be applied. Alternatively, the first electrical potential may be applied to the carrier 102 and then be fed indirectly to the first electrode 110 via said carrier. The first electrical potential may be, for example, the ground potential or some other predefined reference potential.

Furthermore, the electrically active region 106 of the light emitting component 100 may have an organic electroluminescent layer structure 112, which is applied on or above the first electrode 110.

The organic electroluminescent layer structure 112 may include one or a plurality of emitter layers 118, for example including fluorescent and/or phosphorescent emitters, and one or a plurality of hole-conducting layers 116 (also designated as hole transport layer(s) 120). In various embodiments, one or a plurality of electron-conducting layers 116 (also designated as electron transport layer(s) 116) may alternatively or additionally be provided.

Examples of emitter materials which may be used in the light emitting component 100 in accordance with various embodiments for the emitter layer(s) 118 include organic or organometallic compounds such as derivatives of polyfluorene, polythiophene and polyphenylene (e.g. 2- or 2,5-substituted poly-p-phenylene vinylene) and metal complexes, for example iridium complexes such as blue phosphorescent FlrPic (bis(3,5-difluoro-2-(2-pyridyl)phenyl(2-carboxypyridyl) iridium III), green phosphorescent Ir(ppy)3 (tris(2-phenylpyridine)iridium III), red phosphorescent Ru (dtb-bpy)3*2(PF6) (tris[4,4′-di-tert-butyl-(2,2′)-bipyridine]ruthenium(III) complex) and blue fluorescent DPAVBi (4,4-bis[4-(di-p-tolylamino)styryl]biphenyl), green fluorescent TTPA (9,10-bis[N,N-di(p-tolyl)amino]anthracene) and red fluorescent DCM2 (4 dicyanomethylene)-2-methyl-6-julolidyl-9-enyl-4H-pyran) as non-polymeric emitters. Such non-polymeric emitters may be deposited by means of thermal evaporation, for example. Furthermore, it is possible to use polymer emitters, which may be deposited, in particular, by means of a wet-chemical method such as spin coating, for example.

The emitter materials may be embedded in a matrix material in a suitable manner.

It should be pointed out that other suitable emitter materials are likewise provided in other embodiments.

The emitter materials of the emitter layer(s) 118 of the light emitting component 100 may be selected for example such that the light emitting component 100 emits white light. The emitter layer(s) 118 may include a plurality of emitter materials that emit in different colors (for example blue and yellow or blue, green and red); alternatively, the emitter layer(s) 118 may also be constructed from a plurality of partial layers, such as a blue fluorescent emitter layer 118 or blue phosphorescent emitter layer 118, a green phosphorescent emitter layer 118 and a red phosphorescent emitter layer 118. By mixing the different colors, the emission of light having a white color impression may result. Alternatively, provision may also be made for arranging a converter material in the beam path of the primary emission generated by said layers, which converter material at least partly absorbs the primary radiation and emits a secondary radiation having a different wavelength, such that a white color impression results from a (not yet white) primary radiation by virtue of the combination of primary and secondary radiation.

The organic electroluminescent layer structure 112 may generally include one or a plurality of electroluminescent layers. The one or the plurality of electroluminescent layers may include organic polymers, organic oligomers, organic monomers, organic small, non-polymeric molecules (“small molecules”) or a combination of these materials. By way of example, the organic electroluminescent layer structure 112 may include one or a plurality of electroluminescent layers embodied as a hole transport layer 120, so as to enable for example in the case of an OLED an effective hole injection into an electroluminescent layer or an electroluminescent region. Alternatively, in various embodiments, the organic electroluminescent layer structure 112 may include one or a plurality of functional layers embodied as an electron transport layer 116, so as to enable for example in an OLED an effective electron injection into an electroluminescent layer or an electroluminescent region. By way of example, tertiary amines, carbazo derivatives, conductive polyaniline or polyethylene dioxythiophene may be used as material for the hole transport layer 120. In various embodiments, the one or the plurality of electroluminescent layers may be embodied as an electroluminescent layer.

In various embodiments, the hole transport layer 120 may be applied, for example deposited, on or above the first electrode 110, and the emitter layer 118 may be applied, for example deposited, on or above the hole transport layer 120. In various embodiments, electron transport layer 116 may be applied, for example deposited, on or above the emitter layer 118.

In various embodiments, the organic electroluminescent layer structure 112 (that is to say for example the sum of the thicknesses of hole transport layer(s) 120 and emitter layer(s) 118 and electron transport layer(s) 116) may have a layer thickness of a maximum of approximately 1.5 μm, for example a layer thickness of a maximum of approximately 1.2 μm, for example a layer thickness of a maximum of approximately 1 μm, for example a layer thickness of a maximum of approximately 800 nm, for example a layer thickness of a maximum of approximately 500 nm, for example a layer thickness of a maximum of approximately 400 nm, for example a layer thickness of a maximum of approximately 300 nm. In various embodiments, the organic electroluminescent layer structure 112 may have for example a stack of a plurality of organic light emitting diodes (OLEDs) arranged directly one above another, wherein each OLED may have for example a layer thickness of a maximum of approximately 1.5 μm, for example a layer thickness of a maximum of approximately 1.2 μm, for example a layer thickness of a maximum of approximately 1 μm, for example a layer thickness of a maximum of approximately 800 nm, for example a layer thickness of a maximum of approximately 500 nm, for example a layer thickness of a maximum of approximately 400 nm, for example a layer thickness of a maximum of approximately 300 nm. In various embodiments, the organic electroluminescent layer structure 112 may have for example a stack of two, three or four OLEDs arranged directly one above another, in which case for example the organic electroluminescent layer structure 112 may have a layer thickness of a maximum of approximately 3 μm.

The light emitting component 100 may optionally generally include further organic functional layers, for example arranged on or above the one or the plurality of emitter layers 118 or on or above the electron transport layer(s) 116, which serve to further improve the functionality and thus the efficiency of the light emitting component 100.

The second electrode 114 (for example in the form of a second electrode layer 114) may be applied on or above the organic electroluminescent layer structure 110 or, if appropriate, on or above the one or the plurality of further organic functional layers.

In various embodiments, the second electrode 114 may include or be formed from the same materials as the first electrode 110, metals being particularly suitable in various embodiments.

In various embodiments, the second electrode 114 (for example for the case of a metallic second electrode 114) may have for example a layer thickness of less than or equal to approximately 50 nm, for example a layer thickness of less than or equal to approximately 45 nm, for example a layer thickness of less than or equal to approximately 40 nm, for example a layer thickness of less than or equal to approximately 35 nm, for example a layer thickness of less than or equal to approximately 30 nm, for example a layer thickness of less than or equal to approximately 25 nm, for example a layer thickness of less than or equal to approximately 20 nm, for example a layer thickness of less than or equal to approximately 15 nm, for example a layer thickness of less than or equal to approximately 10 nm.

The second electrode 114 may generally be formed in a similar manner to the first electrode 110, or differently than the latter. In various embodiments, the second electrode 114 may be formed from one or more of the materials and with the respective layer thickness, as described above in connection with the first electrode 110. In various embodiments, both the first electrode 110 and the second electrode 114 are formed as translucent or transparent. Consequently, the light emitting component 100 illustrated in FIG. 1 may be designed as a top and bottom emitter (to put it another way as a transparent light emitting component 100).

The second electrode 114 may be formed as an anode, that is to say as a hole-injecting electrode, or as a cathode, that is to say as an electron-injecting electrode.

The second electrode 114 may have a second electrical terminal, to which a second electrical potential (which is different than the first electrical potential), provided by the energy source, may be applied. The second electrical potential may have for example a value such that the difference with respect to the first electrical potential has a value in a range of approximately 1.5 V to approximately 20 V, for example a value in a range of approximately 2.5 V to approximately 15 V, for example a value in a range of approximately 3 V to approximately 12 V.

An encapsulation 108, for example in the form of a barrier thin-film layer/thin-film encapsulation 108, may optionally also be formed on or above the second electrode 114 and thus on or above the electrically active region 106.

In the context of this application, a “barrier thin-film layer” or a “barrier thin film” 108 may be understood to mean, for example, a layer or a layer structure which is suitable for forming a barrier against chemical impurities or atmospheric substances, in particular against water (moisture) and oxygen. In other words, the barrier thin-film layer 108 is formed in such a way that OLED-damaging substances such as water, oxygen or solvent may not penetrate through it or at most very small proportions of said substances may penetrate through it.

In accordance with one configuration, the barrier thin-film layer 108 may be formed as an individual layer (to put it another way, as a single layer). In accordance with an alternative configuration, the barrier thin-film layer 108 may include a plurality of partial layers formed one on top of another. In other words, in accordance with one configuration, the barrier thin-film layer 108 may be formed as a layer stack. The barrier thin-film layer 108 or one or a plurality of partial layers of the barrier thin-film layer 108 may be formed for example by means of a suitable deposition method, e.g. by means of an atomic layer deposition (ALD) method in accordance with one configuration, e.g. a plasma enhanced atomic layer deposition (PEALD) method or a plasmaless atomic layer deposition (PLALD) method, or by means of a chemical vapor deposition (CVD) method in accordance with another configuration, e.g. a plasma enhanced chemical vapor deposition (PECVD) method or a plasmaless chemical vapor deposition (PLCVD) method, or alternatively by means of other suitable deposition methods.

By using an atomic layer deposition (ALD) method, it is possible for very thin layers to be deposited. In particular, layers having layer thicknesses in the atomic layer range may be deposited.

In accordance with one configuration, in the case of a barrier thin-film layer 108 having a plurality of partial layers, all the partial layers may be formed by means of an atomic layer deposition method. A layer sequence including only ALD layers may also be designated as a “nanolaminate”.

In accordance with an alternative configuration, in the case of a barrier thin-film layer 108 including a plurality of partial layers, one or a plurality of partial layers of the barrier thin-film layer 108 may be deposited by means of a different deposition method than an atomic layer deposition method, for example by means of a vapor deposition method.

In accordance with one configuration, the barrier thin-film layer 108 may have a layer thickness of approximately 0.1 nm (one atomic layer) to approximately 1000 nm, for example a layer thickness of approximately 10 nm to approximately 100 nm in accordance with one configuration, for example approximately 40 nm in accordance with one configuration.

In accordance with one configuration in which the barrier thin-film layer 108 includes a plurality of partial layers, all the partial layers may have the same layer thickness. In accordance with another configuration, the individual partial layers of the barrier thin-film layer 108 may have different layer thicknesses. In other words, at least one of the partial layers may have a different layer thickness than one or more other partial layers.

In accordance with one configuration, the barrier thin-film layer 108 or the individual partial layers of the barrier thin-film layer 108 may be formed as a translucent or transparent layer. In other words, the barrier thin-film layer 108 (or the individual partial layers of the barrier thin-film layer 108) may consist of a translucent or transparent material (or a material combination that is translucent or transparent).

In accordance with one configuration, the barrier thin-film layer 108 or (in the case of a layer stack having a plurality of partial layers) one or a plurality of the partial layers of the barrier thin-film layer 108 may include or consist of one of the following materials: aluminum oxide, zinc oxide, zirconium oxide, titanium oxide, hafnium oxide, tantalum oxide, lanthanum oxide, silicon oxide, silicon nitride, silicon oxynitride, indium tin oxide, indium zinc oxide, aluminum-doped zinc oxide, and mixtures and alloys thereof. In various embodiments, the barrier thin-film layer 108 or (in the case of a layer stack having a plurality of partial layers) one or a plurality of the partial layers of the barrier thin-film layer 108 may include one or a plurality of high refractive index materials, to put it another way one or a plurality of materials having a high refractive index, for example having a refractive index of at least 2.

In various embodiments, on or above the encapsulation 108, it is possible to provide an adhesive and/or a protective lacquer 124, by means of which, for example, a cover 126 (for example a glass cover 126) is fixed, for example adhesively bonded, on the encapsulation 108. In various embodiments, the optically translucent layer composed of adhesive and/or protective lacquer 124 may have a layer thickness of greater than 1 nm, for example a layer thickness of several nm. In various embodiments, the adhesive may include or be a lamination adhesive.

In various embodiments, light-scattering particles may also be embedded into the layer of the adhesive (also designated as adhesive layer), which particles may lead to a further improvement in the color angle distortion and the coupling-out efficiency. In various embodiments, the light-scattering particles provided may be dielectric scattering particles, for example, such as metal oxides, for example, such as e.g. silicon oxide (SiO2), zinc oxide (ZnO), zirconium oxide (ZrO2), indium tin oxide (ITO) or indium zinc oxide (IZO), gallium oxide (Ga2Oa), aluminum oxide, or titanium oxide. Other particles may also be suitable provided that they have a refractive index that is different than the effective refractive index of the matrix of the translucent layer structure, for example air bubbles, acrylate, or hollow glass beads. Furthermore, by way of example, metallic nanoparticles, metals such as gold, silver, iron nanoparticles, or the like may be provided as light-scattering particles.

In various embodiments, between the second electrode 114 and the layer composed of adhesive and/or protective lacquer 124, an electrically insulating layer (not shown) may also be applied, for example SiN, for example having a layer thickness in a range of approximately 300 nm to approximately 1.5 μm, for example having a layer thickness in a range of approximately 500 nm to approximately 1 μm, in order to protect electrically unstable materials, during a wet-chemical process for example.

In various embodiments, the adhesive may be designed in such a way that it itself has a refractive index which is less than the refractive index of the cover 126. Such an adhesive may be for example a low refractive index adhesive such as, for example, an acrylate which has a refractive index of approximately 1.3. Furthermore, a plurality of different adhesives forming an adhesive layer sequence may be provided.

Furthermore, it should be pointed out that, in various embodiments, an adhesive 124 may also be completely dispensed with, for example in embodiments in which the cover 126, for example composed of glass, are applied to the encapsulation 108 by means of plasma spraying, for example.

In various embodiments, the cover 126 and/or the adhesive 124 may have a refractive index (for example at a wavelength of 633 nm) of 1.55.

Furthermore, in various embodiments, one or a plurality of antireflective layers (for example combined with the encapsulation 108, for example the thin-film encapsulation 108) may additionally be provided in the light emitting component 100.

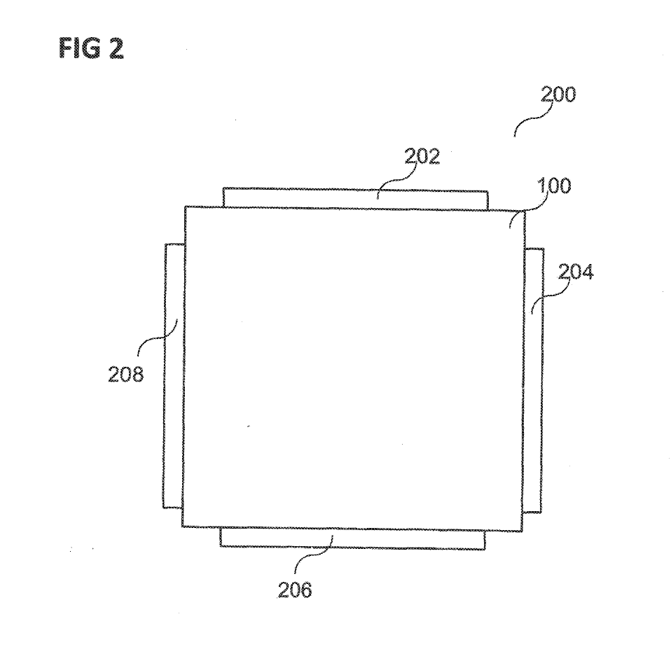

FIG. 2 shows a schematic plan view of the rear side of an optoelectronic component, in accordance with various embodiments.

FIG. 2 schematically illustrates the rear side of an optoelectronic component 100 with electrical contact pads 202, 204, 206, 208.

The shape of the optoelectronic component 100 illustrated in FIG. 2 and the shape and the positions of the electrical contact pads 202, 204, 206, 208 are illustrated as an example without any restriction of generality. Other geometrical shapes and more or fewer contact pads may be formed, for example 1 contact pad, 2 contact pads, 3 contact pads, 5 contact pads, 6 contact pads or more. The number of contact pads may be dependent on the areal size of the optoelectronic component 100 and the demand for the areal uniformity of the emitted or absorbed electromagnetic radiation. Furthermore, the number and shape of the contact pads of an optoelectronic component 100 may be dependent on how many further optoelectronic components 100 are intended to be connected to said optoelectronic component 100, for example are intended to be interconnected therewith.

The contact pads 202, 204, 206, 208 may be electrically connected to the electrodes 110, 114 of the organic component 100.

The contact pads 202, 204, 206, 208 may partly or wholly surround the component 200 and/or may be multilayered, such that an electrical connection may be formed for example from the top side and from the underside of a contact pad, for example top side and underside of a contact pad may have different polarities.

At least one of the contact pads, for example 204, may have a different polarity than the other contact pads, for example 202, 206, 208. In this case, polarity may be understood to mean different exit points or entrance points of charge carriers of a current source.

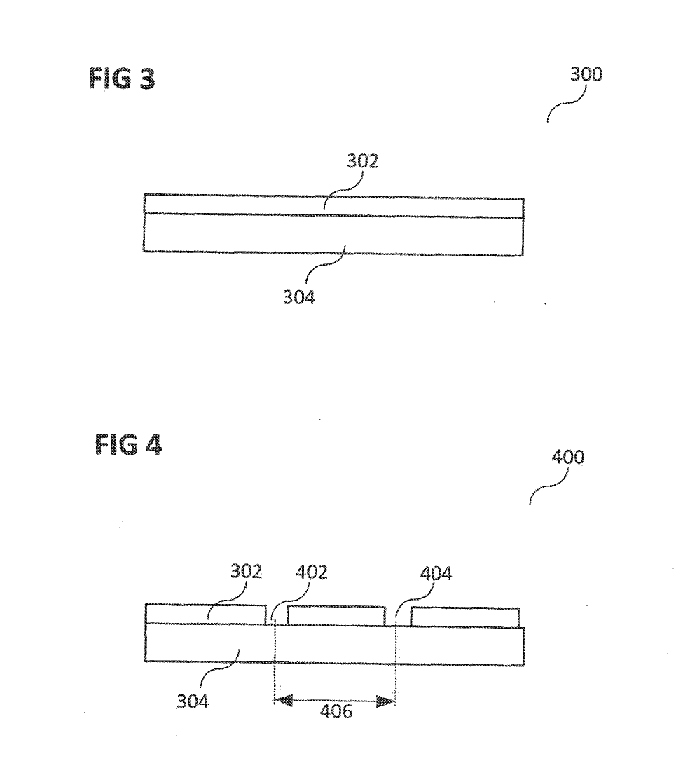

FIG. 3 shows a schematic cross-sectional view of a contact pad of an optoelectronic component, in accordance with various embodiments.

FIG. 3 illustrates a schematic cross-sectional view 300 of the contact pads 202, 204, 206, 208. Part of the contact pads 202 204, 206, 208 is an electrically conductive region 304, which may be electrically coupled to one of the electrodes 110 or 114 of the optoelectronic component.

The electrically conductive region 304 may be formed in a self-supporting fashion or may be applied on a carrier (not illustrated).

An encapsulation 302 may be applied on or above the electrically conductive region 304. The encapsulation 302 may have a constitution similar or identical to the encapsulation 108 of the optoelectronic component 100 and may be formed as electrically non-conducting, i.e. electrically insulating.

FIG. 4 shows a schematic cross-sectional view of a contact pad of an optoelectronic component, in accordance with various embodiments.

FIG. 4 illustrates exposed regions 402, 404 in the encapsulation 302.

The exposed regions 402, 404 may be formed after the formation of the optoelectronic component 100 by means of a mechanical process or a ballistic process.

Mechanical exposure of the regions 402, 404 to be exposed may be formed for example by means of a glass fiber brush.

Ballistic exposure of the regions 402, 404 to be exposed may be realized for example by means of bombardment of the region to be exposed with particles, molecules, atoms, ions, electrons and/or photons.

Bombardment with photons may be implemented for example as a laser with a wavelength in the range of approximately 200 nm to approximately 1500 nm, for example in a focused fashion, for example with a focus diameter in a range of approximately 10 μm to approximately 2000 μm, for example in a pulsed fashion, for example with a pulse duration in the range of approximately 100 fs to approximately 0.5 ms, for example with a power in a range of approximately 50 mW to approximately 1000 mW, for example with a power density of 100 kW/cm2 to approximately 10 GW/cm2 and for example with a repetition rate in a range of approximately 100 Hz to approximately 1000 Hz.

One exposed region or a plurality of exposed regions 402, 404 at a distance 406 from one another may be formed on a contact pad, wherein the distance 406 between the exposed regions and the position of the exposed regions on the contact pad may be formed differently relative to other contact pads and/or further exposed regions of the same contact pad.

The distance 406 between the exposed regions 402, 404 may be formed in a range of approximately 100 μm to approximately 10 cm, for example in a range of 1 mm to approximately 5 cm, for example in a range of approximately 5 mm to approximately 2 cm.

The exposed regions 402, 404 may have or resemble a geometrical shape or a part of a geometrical shape from the group of the following geometrical bodies: cylinder, cone, truncated cone, sphere, hemisphere, cube, parallelepiped, pyramid, truncated pyramid, prism, or a polyhedron.

The conductive regions 304 of the component may also be exposed at the top side or the sides of the component 200 in the non-visible and/or optically inactive region, for example in the region of the mount of the component. Exposure of regions 402, 404 may therefore be formed simultaneously on all sides of the component and also on a plurality of sides.

An exposed region may as a depression having a lateral extent of approximately 100×100 μm2 to approximately 1×1 cm2 and a depth that may correspond to the thickness of the encapsulation layer. However, for example for a mount, the exposed region may also be formed in a thinner fashion or else formed in a thicker fashion, for example for a positively locking connection.

The exposed regions 402, 404 may have an identical or different cross section, i.e. shape.

FIG. 5 shows a schematic cross-sectional view of an electrical, cohesive connection of an optoelectronic component to electrical contacts before the coupling, in accordance with various embodiments.

FIG. 5 illustrates a prepared cohesive connection before an electrical connection of the terminals 502 to the contact pad 400 is formed.

The exposed regions 402, 404 of the encapsulation layer 302 may be partly or wholly filled with a substance 504, 506 or a substance mixture 504, 506 for the cohesive connection.

The substance or the substance mixture of the cohesive connection may have a non-solid state, for example liquid or viscous, for example a non-cured epoxy, a thermally conductive paste, for example a silver-containing paste, soldering tin, or some other liquid metal.

The electrical terminal(s) 502 may be aligned directly above the exposed regions. The contact-making end of the terminals may be formed such that it is flat or tapering, for example conical or spherical (not shown), in order to simplify the alignment of the electrical terminals 502.

The substance or the substance mixture of the encapsulation may be formed as impermeable to the substance or the substance mixture of the cohesive connection.

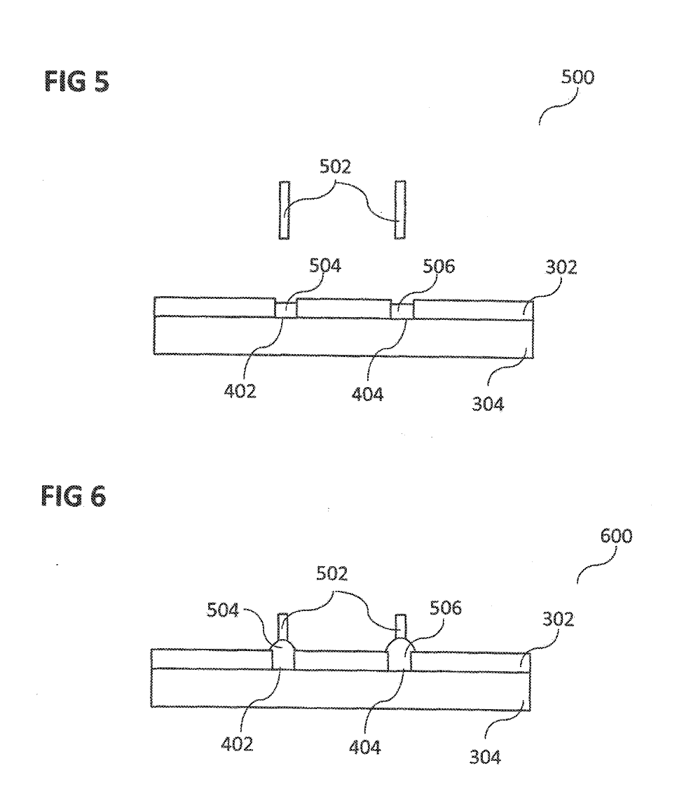

FIG. 6 shows a schematic cross-sectional view of an electrical, cohesive connection of an optoelectronic component to electrical contacts after the coupling, in accordance with various embodiments.

FIG. 6 illustrates a cohesive connection after the electrical terminals 502 were brought into physical contact with the substance or the substance mixture of the cohesive connection 504, 506.

In the case of an electrically conductive substance 504, 506 or substance mixture 504, 506 of the cohesive connection, by means of just physically coupling the electrical terminal 502 to the substance or the substance mixture of the cohesive connection 504, 506 it is possible to form an electrical connection between electrical terminal 502 and electrically conductive region 304, i.e. the dimensioning of the electrical terminals 502 may be smaller than the dimensioning of the exposed regions 402, 404. The alignment of the electrical contacts 504, 506 relative to the exposed regions 402, 404 may be simplified as a result.

In the case of a non-conductive substance 504, 506 or substance mixture 504, 506 of the cohesive connection, an electrical connection between the electrical terminals 502 and the conductive regions 304 may be formed by means of a physical contact.

The shape of the exposed regions 402, 404 may have an aligning effect for the substance 504, 506 or the substance mixture 504, 506 of the cohesive connection and the electrical terminals 502, if the electrical terminals are brought close to the exposed regions.

In this case, an aligning effect may be understood to mean a reduction of deviations of the alignment from the at least partly complementary shape of the electrical terminal 502 relative to the respectively exposed region 402, 404 by means of a lateral force action by means of the shape of the terminal and/or the exposed region.

With regard to the substance or the substance mixture of the cohesive connection, the aligning effect may prevent the substance or the substance mixture from running on the surface of the encapsulation 302.

In this case, preventing the substance or the substance mixture of the cohesive connection from running may be realized by means of adapting the surface tension of the substance or the substance mixture of the encapsulation and the surface tension of the substance or the substance mixture of the cohesive connection.

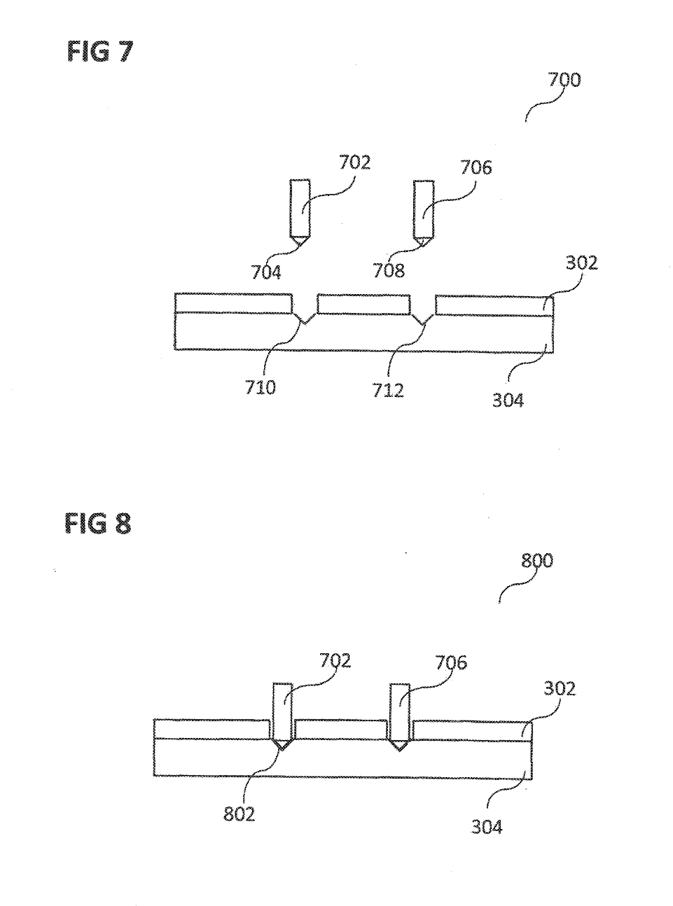

FIG. 7 shows a schematic cross-sectional view of an electrical, positively locking connection of an optoelectronic component to electrical contacts before the coupling in accordance with various embodiments.

FIG. 7 illustrates electrical contacts 702, 706 aligned above the exposed regions 710, 712. The extent of the electrical contacts 702, 706 and of the exposed regions 710, 712 and the ratio of the extent of the electrical contacts 702, 706 and of the exposed regions 710, 712 to one another may deviate from the cohesive connection in FIG. 5.

The electrical connection between the electrical contacts 702, 706 and the conductive region 304 may be formed by means of positively locking engagement of the contacts 702, 706 with the conductive regions 304 and/or the gravitational force and/or a spring force.

In order to facilitate the alignment of the positively locking connection, the electrical terminals 704, 708 and the exposed regions 710, 712 may be shaped in such a way that an aligning effect is formed by means of the shape of the exposed regions and/or terminals.

FIG. 8 shows a schematic cross-sectional view of an electrical positively locking connection of an optoelectronic component to electrical contacts after the coupling, in accordance with various embodiments.

FIG. 8 illustrates a positively locking electrical connection 802 of the electrical contacts 702, 706 to the conductive region 304 from FIG. 7. The connection 802 may be fixed by means of the gravitational force or a spring force, for example a holding device of the component.

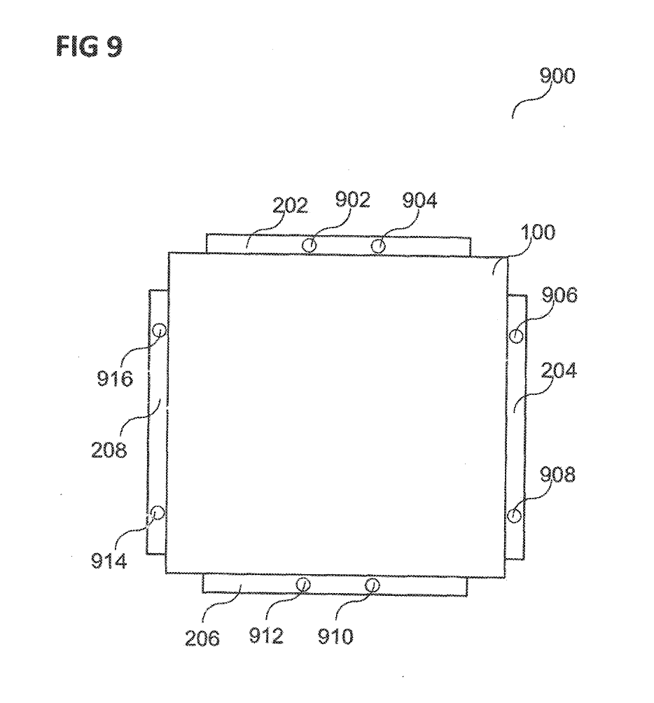

FIG. 9 shows a schematic plan view of the rear side of an optoelectronic component with exposed conductive regions, in accordance with various embodiments.

FIG. 9 schematically illustrates an optoelectronic component 100 with the electrical terminals 202, 204, 206, 208 and the exposed regions 902, 904, 906, 908, 910, 912, 914, 916 of the contact pads 202, 204, 206, 208 in accordance with the descriptions of FIG. 3, FIG. 4, FIG. 5, FIG. 6, FIG. 7 and/or FIG. 8.

Each of the contact pads 202, 204, 206, 208 may have a different number of exposed regions of the encapsulation 302 per contact pad 202, 204, 206, 208, for example none, one, two, three or more; with a different distance 406 between the individual exposed regions 902, 904, 906, 908, 910, 912, 914, 916; and different shapes and extents of the individual exposed regions 902, 904, 906, 908, 910, 912, 914, 916.

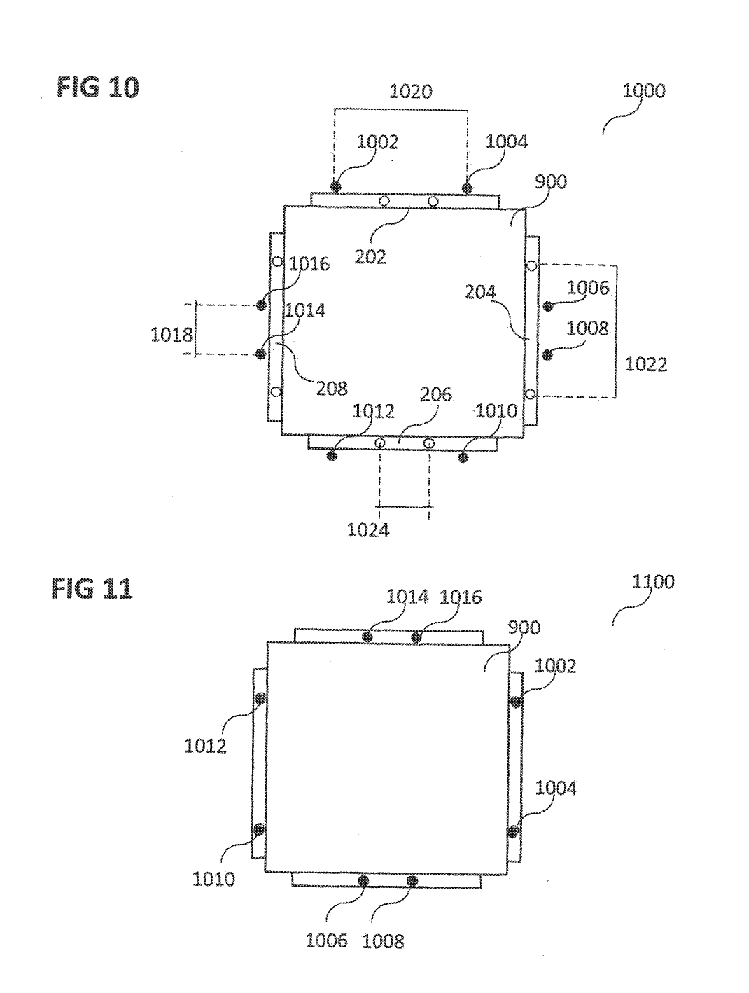

FIG. 10 shows a schematic illustration of polarity reversal protection of an optoelectronic component in the case of incorrect polarity, in accordance with various embodiments.

FIG. 10 illustrates an embodiment of polarity reversal protection of an optoelectronic component. The optoelectronic component may correspond to the component 900 from FIG. 9.

Alongside the component 900, the illustration shows electrical contacts 1002, 1004, 1006, 1008, 1010, 1012, 1014, 1016, the distances 1018, 1020 of which are formed in an invariable fashion, for example as stationary contacts of a holding device.

Opposite contact pads, i.e. 202, 206 and 204, 208; and electrical terminals, i.e. 1002, 1004, 1010, 1012 and 1006, 1008, 1014, 1016; may have an identical polarity.

The distance 1018, 1020 between the electrical terminals 1002, 1004, 1006, 1008, 1010, 1012, 1014, 1016, in the case of incorrect alignment, i.e. polarity reversal, of the component 900, cannot correspond to the distance 1022, 1024 of the exposed regions of the contact pads 902, 904, 906, 908, 910, 912, 914, 916. In other words: no electrical connection may be formed.

Without restricting the generality, given identical polarity of the contact pads, i.e. 202, 206 and 204, 208, and electrical terminals 1006, 1008, 1014, 1016 and 1002, 1004, 1010, 1012, an identical distance 1018, 1020, 1022 and 1024 has been assumed.

FIG. 11 shows a schematic illustration of polarity reversal protection of an optoelectronic component in the case of correct polarity, in accordance with various embodiments.

FIG. 11 illustrates the correct alignment of the component 900 relative to the electrical contact pads from FIG. 10, i.e. the distance between the electrical terminals 1018, 1020 corresponds to the distance between the exposed regions 1022, 1024. An electrical connection may be formed in accordance with FIG. 6 and/or FIG. 8.

With the illustrated embodiment of the electrical terminals 1002, 1004, 1010, 1012 and 1006, 1008, 1014, 1016 and exposed regions 902, 904, 906, 908, 910, 912, 914, 916, an electrical connection may be possible in two alignments of the component 900. By means of using different shapes of the electrical terminals 1002, 1004, 1010, 1012 and 1006, 1008, 1014, 1016 and/or of the exposed regions 902, 904, 906, 908, 910, 912, 914, 916 among one another or a different number of exposed regions 902, 904, 906, 908, 910, 912, 914, 916 per contact pad 202, 204, 206, 208, it is possible to reduce the number of alignment possibilities to one alignment possibility (not shown), without the shape of the component or of the holding device being altered for this purpose.

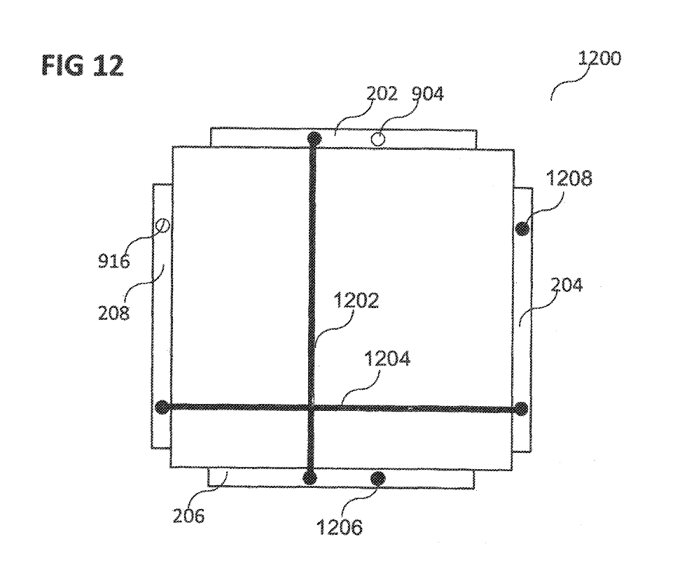

FIG. 12 shows a schematic illustration of a parallel connection of an optoelectronic component, in accordance with various embodiments.

FIG. 12 illustrates an embodiment for electrically connecting a component to a plurality of terminals of identical polarity, wherein an electrical terminal 1002, 1004, 1006, 1008, 1010, 1012, 1014, 1016 is not necessary for every electrical contact pad 202, 204, 206, 208.

Without restricting the generality, the reduction of the necessary number of electrical contacts may be illustrated on the basis of the optoelectronic component 900 from FIG. 9.

Electrical contact pads of identical polarity, i.e. for example 202, 206 and 204, 208; may be electrically connected to one another by means of electrical bridges 1202, 1204, for example with conventional wirings with cohesive or positively locking connection on the optically inactive component underside (if present) or inactive edge regions of the component.

Defined positions for the electrical bridges 1202, 1204 may be realized by means of the exposed regions 902, 908, 912, 914. The defined positions may be used for example for forming the bridges 1202, 1204 in an automated fashion and/or simplify connecting the contact bridges in parallel, since only ever one wiring element, for example one cable, is processed or held per soldering location.

An electrical connection 1206, 1208 to the exposed regions 202 or 206 and 204 or 208 may be formed for the purpose of energizing the component 900.

With a plurality of exposed regions, on the terminals 204 and 206 connected to the electrical contacts 1206, 1208, by means of the electrical bridges 1202 and 1204 it is also possible to energize more than one contact pad 202 and 208 of identical polarity with a respective electrical terminal 1206 and 1208.

The exposed regions 902, 916 of the electronic component 900 that are not required may be used for aligning and/or fixing the electronic component 900, for example if the encapsulation is partly removed; or exposing the unused exposed conductive regions 904, 916 may be omitted in the case of the electronic component 900.

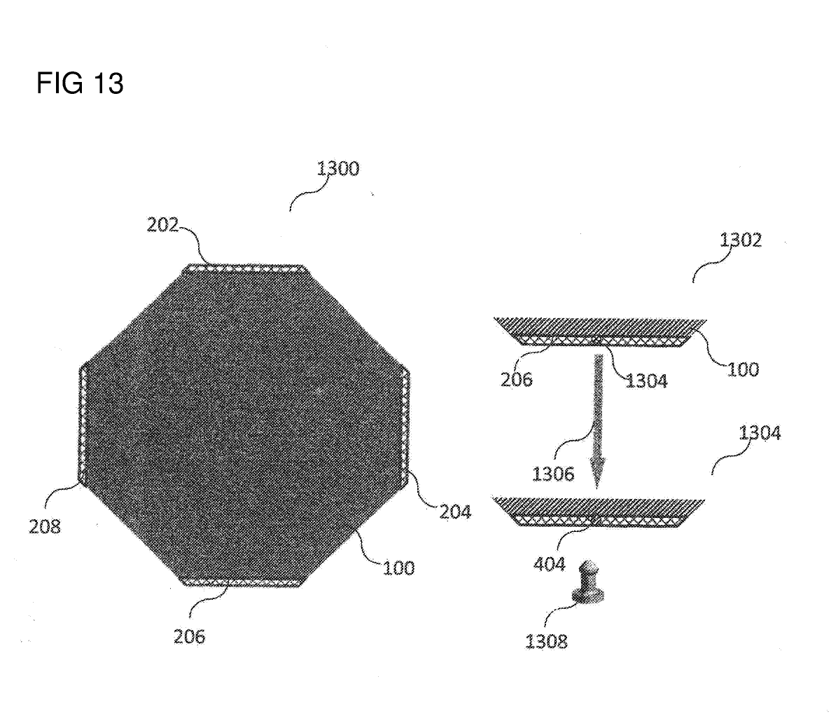

FIG. 13 shows a schematic illustration of a specific embodiment of an optoelectronic component.

FIG. 13 illustrates the rear side of an organic light emitting diode 1300 as a first specific embodiment of the optoelectronic component 200.

The detail enlargement 1302 illustrates the contact pad 206, for example. A laser beam 1304 may be focused on the contact pad 206.

A device for ballistic exposure by means of photons may be formed for example as a laser, for example with a wavelength of approximately 248 nm with a focus diameter of approximately 400 μm with a pulse duration of approximately 15 ns and an energy of approximately 18 mJ.

By means of the irradiation 1306, the encapsulation 302 (see FIG. 3) may be removed and the electrically conductive region 304 may be exposed. The extent and the shape of the exposed regions 404 may be set by means of the degree of focusing, i.e. the diameter of the focal point of the laser beam and the convergence thereof, and the power of the beam source.

The electrical connection of the contact pad 206 to the electrical terminal 1308, for example an electromechanical terminal pin 1308, may be formed as an electrical cohesive and/or electrical positively locking connection in accordance with FIG. 6 and/or FIG. 8.

The component 1300 may have an extent of approximately 15×15 cm2.

In various embodiments, electronic components and a method for producing them are provided with which it is possible to form precise soldering connections and polarity reversal protection.

Contact pads in organic light emitting diodes or other electronic components may furthermore be embodied with a large area and thus offer space for different contact-making scenarios. By means of the exposed regions of the contact locations, it is possible to form different contact locations for different applications. As a result, it is possible to dispense with additional soldering resists or structurings of the contact pads, which might lead to current notches, during manufacture.

While the disclosed embodiments have been particularly shown and described with reference to specific embodiments, it should be understood by those skilled in the art that various changes in form and detail may be made therein without departing from the spirit and scope of the disclosed embodiments as defined by the appended claims. The scope of the disclosed embodiments is thus indicated by the appended claims and all changes which come within the meaning and range of equivalency of the claims are therefore intended to be embraced.

What is claimed is:

1. An electronic component, comprising:
an electrically active region, comprising:
a first contact pad;
a second contact pad;
an organic functional layer structure between the first contact pad and the second contact pad;
wherein the electrically active region is covered with a thin-film encapsulation,
wherein the thin-film encapsulation comprises a first thin-film encapsulation directly on the first and/or second pad and a second thin-film encapsulation over the organic functional layer structure;
wherein the first contact pad and/or the second contact pad comprise(s) an electrically conductive region,
wherein the first thin-film encapsulation and the second thin-film encapsulation have an identical constitution;
at least one electrical terminal, which is coupled to the first contact pad or to the second contact pad, and
wherein the first thin-film encapsulation partly covers the electrically conductive region in such a way that a region of the first contact pad or of the second contact pad is exposed, wherein the exposed region of the first contact pad or of the second contact pad is completely laterally surrounded by the first thin-film encapsulation, and
a positively locking engagement means and/or a cohesive connection means coupling the electrical terminal to the exposed region of the first contact pad or of the second contact pad.

2. The electronic component as claimed in claim 1,
wherein the positively locking engagement is laterally surrounded by the first thin-film encapsulation.

3. The electronic component as claimed in claim 1,
wherein the substance or the substance mixture to form the cohesive connection is laterally surrounded by the first thin-film encapsulation.

4. The electronic component as claimed in claim 1,
wherein the first contact pad, the organic functional layer structure and the second contact pad are arranged one above another in a planar fashion or wherein the first contact pad, the organic functional layer structure and the second contact pad are arranged alongside one another in a planar fashion.

5. The electronic component as claimed in claim 1,
wherein the first contact pad and/or the second contact pad at least partly surround(s) the organic functional layer structure.

6. The electronic component as claimed in claim 1,
wherein for coupling the at least one electrical terminal to the first contact pad and/or the second contact pad the electrical terminal in the exposed region of the first contact pad and/or of the second contact pad forms a physical and electrical connection or only an electrical connection to the first contact pad and/or to the second contact pad.

7. The electronic component as claimed in claim 1,
wherein the at least one electrical terminal in physical contact with the first thin film encapsulation has or forms no electrical connection to the first contact pad and/or the second contact pad.

8. The electronic component as claimed in claim 1,
wherein in the case of corresponding polarity of the first contact pad and respective terminals and/or of the second contact pad and respective terminals, the exposed regions of the first contact pad or of the second contact pad are formed according to physical and chemical parameters which are complementary to the physical and chemical characteristics of the terminals.

9. The electronic component as claimed in claim 8,
wherein the complementary form of the exposed region comprises the complementary selection of at least one parameter from the group of the following parameters:
shape;
topography; and
chemical constitution of the surface.

10. The electronic component as claimed in claim 1,
wherein the electronic component comprises an organic optoelectronic component.

11. The electronic component as claimed in claim 10,
wherein the organic optoelectronic component is an organic light emitting diode or an organic solar cell.

12. The electronic component as claimed in claim 1, further comprising:
a first electrode and a second electrode, wherein the organic functional layer structure is arranged between the first electrode and second electrode and between the first contact pad and the second contact pad.

13. The electronic component as claimed in claim 12,
wherein the first thin-film encapsulation is directly on the first and/or second pad and the second thin-film encapsulation is directly over the second electrode and organic functional layer structure.

14. The electronic component as claimed in claim 12,
wherein the second electrode and the first contact pad and/or the second contact pad are each substantially planar and arranged substantially parallel to the plane of the organic functional layer structure.

15. The electronic component as claimed in claim 1,
wherein a cover is arranged over the second thin-film encapsulation leaving the first thin-film encapsulation exposed with respect to the cover.

16. The electronic component as claimed in claim 1,
wherein the first thin-film encapsulation and the second thin-film encapsulation have a layer thickness of approximately 0.1 nm to approximately 1000 nm.

17. The electronic component as claimed in claim 1, wherein the positively locking engagement means and/or the cohesive connection means electrically couples the electrical terminal to the exposed region of the first contact pad or of the second contact pad.

18. The electronic component as claimed in claim 1,
wherein the cohesive connection couples the electrical terminal to the exposed region of the first contact pad or of the second contact pad, the cohesive connection comprising a substance or a substance mixture.

19. A method for producing an electronic component, the method comprising:
forming an electrically active region, comprising:
forming a first contact pad;
forming an organic functional layer structure; and
forming a second contact pad;
forming an encapsulation in form of a thin-film encapsulation,
wherein the thin-film encapsulation comprises a first thin-film encapsulation directly on the first contact pad and/or second contact pad and a second thin-film encapsulation over the organic functional layer structure;
wherein the first thin-film encapsulation and the second thin-film encapsulation have an identical constitution;
coupling at least one electrical terminal to the first contact pad or to the second contact pad, and
wherein the first contact pad and/or the second contact pad are/is formed with the first thin-film encapsulation and an electrically conductive region, wherein the first thin-film encapsulation is partly removed from the first contact pad or from the second contact pad, wherein a part of the first contact pad or of the second contact pad is exposed in such a way that the exposed region is completely laterally surrounded by the first thin-film encapsulation and is coupled to the electrical terminal by a positively locking engagement means and/or by a cohesive connection means.
